(19) United States
(12) Patent Application Publication
(10) Pub. No.: US 2014/0202378 A1
(43) Pub. Date: Jul. 24, 2014

(54) METHOD FOR PRODUCING AN ORGANISED NETWORK OF SEMICONDUCTOR NANOWIRES, IN PARTICULAR MADE OF ZnO

(71) Applicant: Commissariat A L'Energie Atomique Et Aux Energies Alternatives, Paris (FR)

(72) Inventors: Robin THIERRY, Chambery (FR); Pierre FERRET, Grenoble (FR); Matthieu LAFOSSAS, Monestier De Clermont (FR); Guillaume PERILLAT-MERCEROZ, Grenoble (FR)

(73) Assignee: Commissariat A L'Energie Atomique Et Aux Energies Alternatives, Paris (FR)

(21) Appl. No.: 14/225,854

(22) Filed: Mar. 26, 2014

Related U.S. Application Data
(63) Continuation of application No. PCT/FR2012/052404, filed on Oct. 19, 2012.

(30) Foreign Application Priority Data
Oct. 21, 2011 (FR) 11.59540

(51) Int. Cl. H01L 21/02

(52) U.S. Cl. CPC H01L 21/02639; H01L 21/02603; H01L 21/02554; H01L 21/0262; Y10S 977/891; B82Y 40/00
USPC 117/104; 977/891

(57) ABSTRACT

A method of forming an organized network of ZnO nanowires including the steps of obtaining, on a substrate, a ZnO layer of Zn polarity, by epitaxial growth at low temperature, advantageously in the range from 400° C. to 650° C., and advantageously in the presence of dioxygen (O2); forming, on this layer, a mask provided with openings for the subsequent growth of nanorods; epitaxially growing ZnO nanorods.

### FIELD OF THE INVENTION

The present invention relates to the growth of semiconductor nanowires (also called nanorods) on a substrate. In particular, the invention relates to the organized growth of semiconductor ZnO, which belongs to the family of II-VI semiconductors.

The main fields of application of ZnO are optoelectronic applications, sensor or transducer applications.

### BACKGROUND

Since the years 2000, many devices using nanorods have been provided (see, for example, Y. Cui and C. M. Lieber, SCIENCE 291, 5501 (2001): 851-853). The first devices often used to be based on a single nanorod and the devices thus obtained generally did not apply beyond the academic field. Little by little, the collective treatment of nanorods has improved and has provided devices based on an assembly of nanorods. However, such nanorods, generally obtained by spontaneous growth on a substrate, would not appear in the form of an organized network.

Now, for most envisaged applications (optoelectronics, sensor, actuator . . . ), the possibility of obtaining organized and controlled networks of nanorods appears as a key element of future devices.

In the specific case of the growth of ZnO nanorods, several documents describe methods aiming at obtaining organized networks of nanorods.

Thus, document Sang Hyun Lee et al. (NANO LETTERS 8, no. 8 (2008): 2419-2422) describes the selective catalytic growth on ZnO strips of Zn polarity. The implemented growth method is molecular beam epitaxy (MBE).

More specifically, the method described in this document is based on the succession of the steps of:
growth of a MgO layer of 8 nanometers, deposited by MBE on a sapphire substrate;
growth of a ZnO layer of Zn polarity deposited by MBE;
lithography and etching to obtain a pattern (pitch 5 micrometers/line), to only keep MgO<2.7 nanometers;
new growth of a ZnO layer, with an O polarity on the etched areas and a Zn polarity on thicker areas.

Such a method effectively enables to obtain the growth along the strip. However, this localization is partial since there is no specific localization along the etched strips. A second disadvantage is that the determination of the polarity by etching is extremely difficult to control since the limiting thickness of the polarity inversion at 2.7 nanometers is a critical value. Further, such an approach implies the compulsory presence of a structured MgO layer on the substrate.

Document S. Xu et al. (J. AM. CHEM. SOC. 130, no. 45 (2008): 14958-14959) describes the local and organized hydrothermal growth of ZnO nanorods. The localization is achieved by using a mask preventing the growth of the material, except at locations where openings are formed. This is the most currently-used method to obtain organized nanorods.

More specifically, this document implements the following conditions:
the growth substrate is a silicon wafer covered with a thin polycrystalline ZnO layer. It should be specified that this layer is formed of grains having a random orientation in the plane;
the polymer mask (PMMA) is then deposited;
an e-beam lithography then enables to form the pattern;
the hydrothermal growth is carried out at a temperature <100° C.

Such a method is limited to low-temperature growths due to the use of a polymer mask, which strongly limits the quantity of obtained material. Further, due to the size of the grains of the polycrystalline nucleation layer, multiple nanorod growths can be observed in the patterns.

### BRIEF DESCRIPTION OF THE INVENTION

The basic principle of the invention is to use, as a nucleation layer, a material having a polarity which is adapted and promotes the growth of nanorods, an organized network thereof being desired to be obtained. In the specific case of ZnO nanorods having a Zn polarity, the nucleation layer is preferably made of ZnO of Zn polarity.

The present invention describes the way to obtain this type of nucleation layer, the way to structure it, and then the nanorod growth method.

According to a first aspect, the present invention relates to a method of forming an organized network of nanorods comprising a semiconductor material, at least binary, from the II-VI family, comprising the steps of:
obtaining a layer of an at least binary semiconductor material, having a surface of (0001) orientation, of same polarity as the nanorods;
forming on this surface a mask provided with openings for the subsequent growth of nanorods;
epitaxially growing the nanorods.

According to a preferred embodiment, the at least binary semiconductor material from the II-VI family is zinc oxide (ZnO). Thus, the nanorods are made of ZnO and at least one of the layer surfaces, advantageously the entire layer, is made of ZnO and has a Zn polarity.

The method according to the invention then develops as follows:
obtaining of a ZnO layer with a (0001) surface of Zn polarity;
forming, on this surface, of a mask provided with openings for the subsequent growth of nanorods;
epitaxial growth of the nanorods.

The material used may also be doped. Such a doping may be formed by the usual dopant elements, such as for example aluminum or gallium for n-type dopants.

The thickness of such a nucleation layer is typically in the range from 100 nanometers to 10 micrometers.

Typically according to the invention, said layer has a (0001) crystal orientation, thus defining two polarities. At least the surface intended to receive the mask and which will have the nanorods grow thereon should have the same polarity as the nanorods, advantageously ZnO of Zn polarity.

In relation with ZnO, the first step of the method according to the invention thus comprises obtaining, on a substrate of interest, a ZnO layer of Zn polarity. In adapted fashion, this layer is obtained by epitaxial growth on said substrate.

Advantageously, the epitaxial growth of this layer is performed at low temperature, advantageously in the range from 400° C. to 650° C., and more advantageously still in the range from 510 to 530° C., for example, at 520° C. Such a temperature enables to obtain a ZnO layer having the desired Zn polarity.

Further, the used oxygen precursor advantageously is dioxygen or O₂, adapted to the envisaged temperature range.

Thus, and more specifically, the invention relates to a method of forming an organized network of ZnO nanorods comprising the steps of:
obtaining, on a substrate, a ZnO layer of Zn polarity, by epitaxial growth at low temperature, advantageously in the range from 400° C. to 650° C., and in the presence of oxygen, advantageously O₂;
forming, on this layer, a mask provided with openings for the subsequent growth of nanorods;
epitaxially growing ZnO nanorods.

The epitaxial growth of the ZnO layer of Zn polarity is advantageously carried out by MOCVD (MetalOrganic Chemical Vapor Deposition).

The temperature range determined as appropriate to obtain the desired polarity, that is, from 400° C. to 650° C., or even from 510 to 530° C., for example, 520° C., is compatible with such a deposition technique. Other deposition techniques can be envisaged, such as molecular beam epitaxy (MBE).

In the context of a deposition, particularly by MOCVD, enabling to obtain a ZnO layer, the following metal-organic precursors are conventionally used:
for oxygen, O₂ or N₂O;
for zinc, DiethylZinc (DEZn) or DimethylZinc (DMZn).

As mentioned hereafter, the oxygen precursor advantageously is dioxygen or O₂.

Regarding the substrate having the ZnO layer of Zn polarity obtained thereon, the method according to the invention enables to form such a layer on a great variety of substrates: it may particularly be a sapphire or glass substrate, or a metal substrate.

Before the deposition of the nucleation layer, the substrate may be submitted to an anneal to clean its surface. Such an anneal is conventionally carried out at a temperature in the order of 1,000° C., for example, 1,070° C., and typically under a O₂ atmosphere.

It should be noted that the presence of a MgO buffer layer of more than 3 nm is not necessary. Thus, and according to a specific embodiment, the substrate comprises no MgO layer, in particular on its upper surface where the ZnO deposition is performed (buffer layer). However, it may be envisaged to perform a deposition on a substrate covered with a buffer layer, in particular a silicon substrate (Si), covered with a buffer layer such as an aluminum nitride layer (AlN). Indeed, such a buffer layer enables to avoid the forming of an intermediate SiO₂ layer on deposition of the ZnO layer.

Given the targeted applications, in addition to a good crystal quality and the desired polarity, the surface of the nucleation layer should be as planar as possible. This can be optimized by means of anneals performed at the end of the deposition of the first ZnO layer of Zn polarity, typically at a temperature in the order of 1,000° C., for example, 1,005° C., under an oxidizing atmosphere, typically made of a mixture of O₂ and of N₂O.

According to a specific embodiment, a second ZnO nucleation layer may be deposited at the surface of the first one, particularly to improve the crystal quality. This deposition may be performed at higher temperature, typically in the range from 700 to 1,000° C., for example, equal to 975° C. Similarly, this other layer is advantageously deposited by MOCVD.

Given the temperature range involved at this step, the following precursors may be used:
for oxygen, O₂ or N₂O, advantageously N₂O;
for zinc, DiethylZinc (DEZn) or DimethylZinc (DMZn).

For the deposition of these layers, the ratio of the molar quantities of type-VI (O) and type-II (Zn) precursors is also important to ensure the evenness of the growth: it is advantageously greater than or equal to 1,000 in the case of ZnO, for example, equal to 1,000 for the low-temperature epitaxial growth with O₂ and DeZn, and equal to 6,700 for the high-temperature epitaxial growth with N₂O and DeZn.

The second step of the method according to the invention comprises depositing a mask on this planar surface of adapted polarity and of forming, in this mask, openings allowing the subsequent growth of nanorods.

The nature of the mask should be adapted to the growth temperatures and should allow the subsequent growth of nanorods in the openings, and not on the mask. It should further enable to easily create openings in the mask, in particular by the electron beam lithography technique. Thus, an adapted mask is advantageously of inorganic nature, for example, Si₃N₄ or SiO₂, advantageously Si₃N₄.

This mask may be deposited by PECVD (Plasma-Enhanced Chemical Vapor Deposition). The openings are advantageously formed by electron beam lithography. Finally, and conventionally, the mask is for example etched by RIE (Reactive Ion Etching).

The next step comprises providing the epitaxial growth of nanorods from the nucleation surface having the same polarity as the nanorods, particularly made of ZnO of Zn polarity, and in the openings formed in the mask.

Remarkably, the growth may be provided in the absence of catalyst, advantageously by the MOCVD technique.

In the same way as for the layer growth and in the specific case of ZnO, the precursors used may be O₂ or N₂O for oxygen, advantageously N₂O, and diethylZinc (DEZn) or dimethylZinc (DMZn) for zinc.

The growth temperature is advantageously high, in the range from 700° C. to 1,000° C., and typically in the order of 880° C.

Here again, the ratio of the molar quantities of type-VI (O) and type-II (Zn) precursors is important to promote the growth of nanorods: in the case of ZnO, it is advantageously lower than 1,000, more advantageously in the range from 100 to 1,000, for example, equal to 600.

The growth duration is adjusted according to the height desired for the nanorods.

The following advantages over prior art can already be observed:
the forming of the ZnO layer of controlled polarity only involves appropriate growth parameters, particularly the epitaxial growth temperature. No previous growth of another material is required. The thickness of this layer is not critical, only the growth method enabling to control the polarity thereof is important.
the different layers (at steps 1 and 3) may be grown by MOCVD, which is the most current industrial method for forming most optoelectronic components. The structuring (step 2) uses methods and equipment usual in microelectronics.
the nucleation rates and the nanorod position control greatly exceed the results published to date.
the method has the advantage of not involving materials other than that of the mask. In optoelectronic applications, any non-functional material potentially is a source of pollution and impurities for devices. Due to the high temperatures required by the growth of nanorods of high crystal quality, a diffusion is capable of occurring from these materials to the active areas of the devices. Such a constraint is for example very strong for catalytic nanorod growths. As for this, the present technology is thus clean.
further, the method according to the invention allows the growth of nanorods at high temperature. This parameter is essential to obtain a high-quality material, which is a major criterion for optoelectronic applications and the forming of high-performance devices.

At the end of the method according to the invention, an organized network of semi-conductor nanorods, in particular from the II-VI family, and particularly made of ZnO, is obtained.

According to another aspect, the present invention thus relates to a structure comprising a layer of an at least binary semiconductor material, advantageously ZnO, with at least its surface having an orientation (0001) of same polarity as the nanorods, advantageously of Zn polarity. According to the invention, said surface is covered with a mask provided with openings having nanorods of said semiconductor material, advantageously ZnO of Zn polarity, located therein.

According to a specific embodiment, the layer of the at least binary semiconductor material, advantageously ZnO of Zn polarity, is located at the surface of a substrate, for example, made of sapphire. The thickness of this nucleation layer may vary from 100 nanometers to 10 micrometers. It may possibly be doped with aluminum or gallium (n-type dopants).

Another variation relates to the use of a Si substrate which enables to work on larger surface areas (300 nanometers) and to have back-side contacts if the selected substrate is heavily doped. In this case, the following stack may be formed:
growth of an AlN layer on Si, advantageously by MOCVD;
then, growth of the layer of the at last binary semiconductor material, advantageously ZnO of ZN polarity, on the AlN layer.

Finally, low-cost substrates having advantageous properties such as transparency (glass substrate), conductivity, and flexibility (low-thickness metal substrate) may be used. The indispensable condition remains the forming, on this substrate, of a thin (0001) layer of same polarity as the nanorods, here of Zn polarity in the case of ZnO. This is made possible due to the method of the present invention.

As already mentioned, the mask is advantageously of inorganic nature, for example, Si₃N₄ or SiO₂, advantageously Si₃N₄.

The openings formed in the mask, advantageously created by electron beam lithography, typically have a diameter of 100 nanometers and are separated from one another by a distance in the range from 300 nanometers to 1 micrometer. The pattern of these openings defines the organized nanorod network.

The nanorods of the at least binary semiconductor material, having a polarity identical to that of the layer surface, advantageously made of ZnO of Zn polarity, thus appear in the form of an organized network, since their growth occurs from the layer, perpendicularly thereto, and through the openings. Their diameter, typically equal to 100 nanometers, is defined by the diameter of the openings, while their height, typically in the range from 1 to 10 micrometers, may be controlled by the growth conditions, particularly the duration.

The fields of application are those where the organization and the accurate control of the size of nanostructures are important. Thus, all devices requiring steps of nanorod integration, functionalization, and contact forming are concerned. This comprises the forming of optoelectronic emission devices (LEDs, Lasers, . . . ) or optical absorption (PV, . . . ), particular in the UV range. The organization of the nanorods allows a simplified use of the material as a transparent electrode in dye-sensitized solar cells. In piezoelectric applications, the accurate control of the dimensions of nanorods eases their integration and the collection of the electric current.

According to another aspect, the invention also relates to an optoelectronic device comprising a structure such as described hereabove.

### BRIEF DESCRIPTION OF THE DRAWINGS

The foregoing features and advantages will now be discussed in the following non-limiting description of a specific embodiment, in relation with the accompanying drawings, among which:

FIG. 1 shows the different phases implemented to form a ZnO layer of good crystal quality and of Zn polarity, particularly the associated temperature variations.

FIG. 2 corresponds to images obtained by scanning electron microscopy (SEM) of the surface of the ZnO layer of Zn polarity after anneal (A) and after the beginning of the high-temperature growth (B), as well as to an AFM (Atomic Force Microscopy) image of the final surface (5×5 μm) (C).

FIG. 3 shows the mask patterns after etching.

FIG. 4 shows the schematic diagram of the local growth of ZnO nanorods.

FIG. 5 corresponds to SEM views of:
A/ the free growth of ZnO nanorods on a sapphire substrate;
B/ the local growth of ZnO nanorods on ZnO/sapphire obtained by the implementation of the method according to the invention.

### EMBODIMENTS OF THE INVENTION

The method according to the invention will be further illustrated in relation with the forming of local structures, based on ZnO nanorods.

### I/ Step 1=Forming of A Layer of Good Crystal Quality and of Zn Polarity

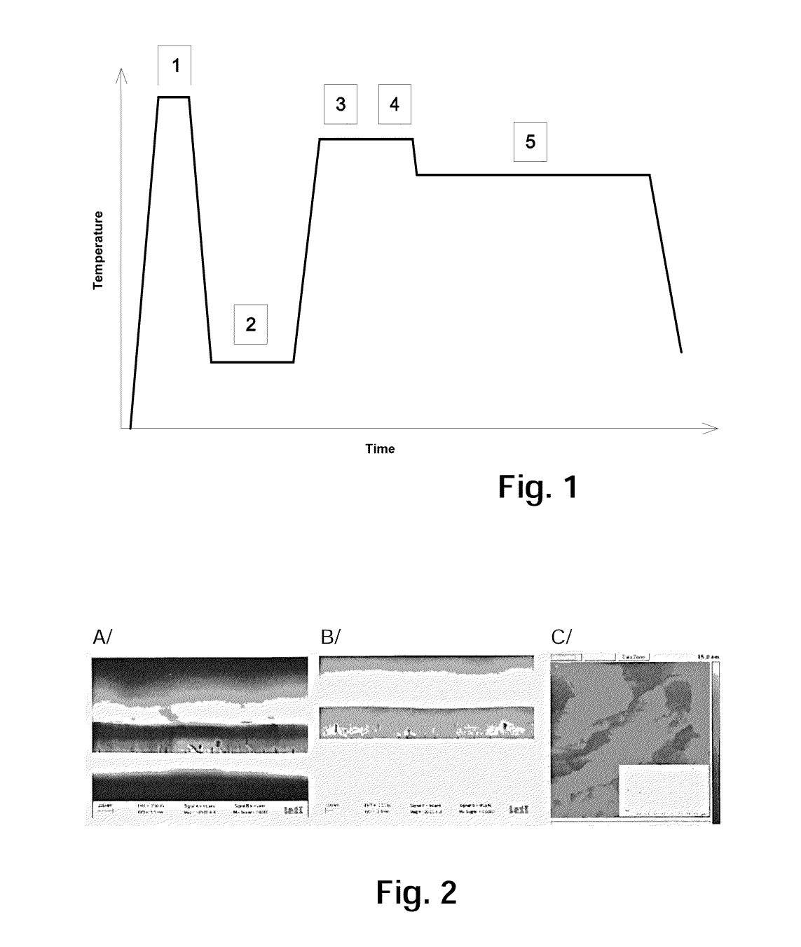

First (1, FIG. 1), the substrate (5) may be submitted to an anneal to clean its surface, at 1,070° C. under an O₂ atmosphere.

In MOCVD, a nucleation layer according to the invention (1) can be obtained by a growth in three phases:
the forming of an epitaxial ZnO layer on sapphire (0001) (5), at low temperature (T in the range from 510 to 530° C., typically at 520° C.) and with, as precursors, O₂ and DiethylZinc (DEZn) or DimethylZinc (DMZn). This first step (noted 2 in FIG. 1) determines the polarity of the ZnO layer. The ratio of the molar quantities of type-VI precursors (O) and of type-II precursors (Zn) is important and conditions the evenness of the growth. To obtain a layer of low roughness, a ratio VI/II of 1,000 is used during this step. The layer has an approximate 450-nanometer thickness.
a possible surface reconstruction anneal, aiming at further improving the layer evenness as well as at decreasing the quantity of defects of the previous layer (noted 3 in FIG. 1). It enables to prepare the third step, that is, the high-temperature growth. This anneal is optimal when it is carried out at 1,005° C. under an oxidizing atmosphere formed of a mixture of O₂ and N₂O.
step 4 of FIG. 1 corresponds to a high-temperature treatment at a 1,005° C. temperature and in the presence of precursors DEZn and N₂O. A 150-nm growth can be observed.
the high-temperature growth of a high-quality ZnO layer epitaxially with the annealed layer (noted 5 in FIG. 1). For this step, DEZn and N₂O are used as precursors and introduced into the reactor with a molar ratio VI/II of 6,700. The growth is carried out at 975° C.

The obtained surface 1 is smooth and of good quality (FIG. 2), that is, it has a shiny aspect equivalent to a high-quality optical-grade polishing. There is a density of local defects, having a density lower than 10⁶ cm⁻². Such a density is low as compared with the rod densities targeted in the rest of the process and has no significant incidence. Apart from these local defects, the typical roughness of such a surface is in the range from 1 to 2 nm RMS (measured by AFM, “Atomic Force Microscopy”).

II/ Step 2=Deposition of a Si₃N₄ Mask on the ZnO layer of Zn Polarity

A Si₃N₄ mask 2 is deposited on the ZnO layer of Zn polarity.

After, patterns 3 used for the localization of the nanorod growth (3rd step described hereafter) are created in the mask.

In practice, this step is carried out as follows:
deposition of Si₃N₄: the deposition is performed by methods usual in micro-electronics. A simple and appropriate technique comprises depositing Si₃N₄ by PECVD at approximately 280° C., which results in the forming of silicon nitride having an imperfect stoichiometry (it is thus spoken of SiₓN_{y}) but sufficient to be used as a selective nucleation mask;
e-beam lithography. The dimension and the spacing of the openings condition the good subsequent growth of ZnO in the form of nanorods. The obtaining of nanorods with the growth conditions described at step 3 hereafter is promoted for patterns having an approximate 100-nanometer diameter, with a pitch in the range from 300 nanometers to 1 micrometer; removal of the illuminated resin;
etching of the Si₃N₄ by RIE through the holes left by the removal of resin. The selectivity of the ions used allows a good opening of the patterns while avoiding a degradation of the ZnO surface, once it has been reached.

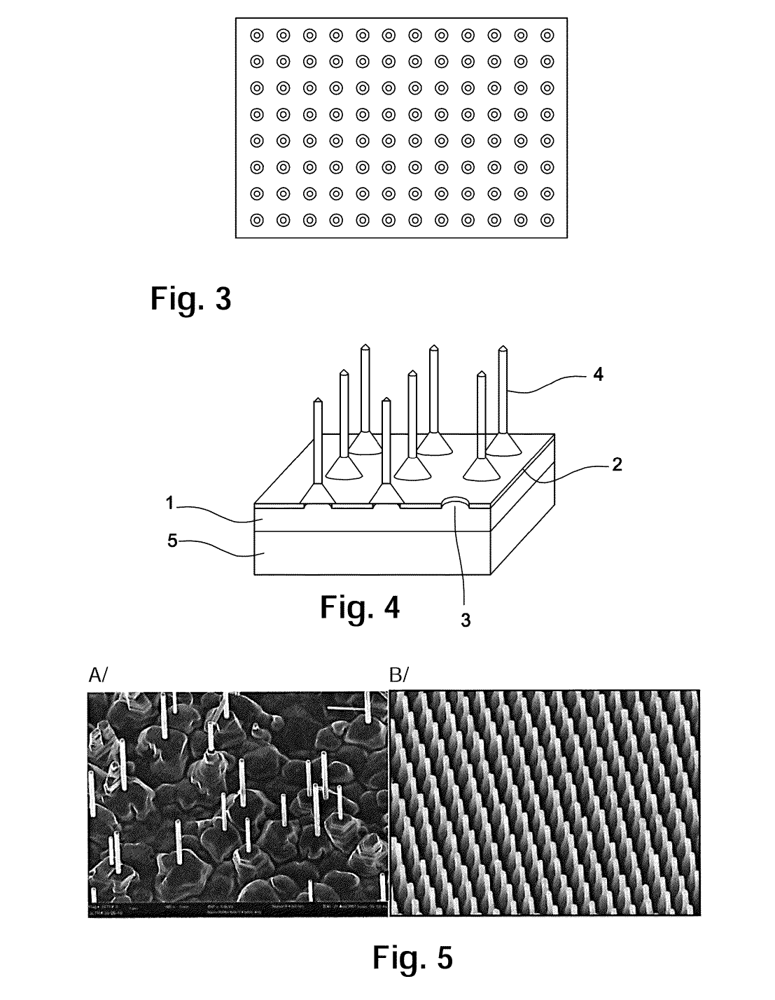

The mask patterns after etching are illustrated in FIG. 3.

III/ Step 3=ZnO Nanorod Growth

ZnO nanorods 4 are grown on the patterned substrate. Thereby, nanorods 4 only grow in openings 3 of SiN mask 2, epitaxially with ZnO layer 1 of Zn polarity.

The growth occurs as follows:
temperature rise under an oxidizing atmosphere (N₂O). The growth temperature is 880° C.;
the work pressure is 120 mbar in the reactor during the growth;
the carrier gas is nitrogen (N₂);
DEZn and N₂O are used as precursors of zinc and oxygen, respectively. Ratio

VI/II is here still very important and conditions the good morphology of the growth. A ratio of 600 enables to obtain ZnO nanorods having a height of 3 μm and a diameter of 100 nanometers after 1,500 seconds of growth.

FIG. 4 is a diagram showing the structure obtained at the end of the described method.

The obtaining of an organized network of ZnO nanorods, due to this method, is shown in FIG. 5B as compared with a free network of ZnO nanorods on a sapphire substrate (FIG. 5A).

1. A method of forming an organized network of ZnO nanowires comprising the steps of:
obtaining, on a substrate, a ZnO layer of Zn polarity, by epitaxial growth at low temperature, advantageously in the range from 400° C. to 650° C., and advantageously in the presence of oxygen, advantageously (O₂);
forming, on this layer, a mask provided with openings for the subsequent growth of nanorods;
epitaxially growing ZnO nanorods.

2. The method of forming an organized network of ZnO nanorods of claim 1, wherein the epitaxial growth of the layer is carried out by means of the MOCVD technique.

3. The method of forming an organized network of ZnO nanorods of claim 1, wherein the epitaxial growth of the layer is carried out at a temperature in the range from 510° C. to 530° C.

4. The method of forming an organized network of ZnO nanorods of claim 1, wherein the substrate having the layer obtained thereon is a sapphire substrate or a Si substrate covered with a buffer layer, such as an AlN layer.

5. The method of forming an organized network of ZnO nanorods of claim 1, wherein the mask is made of inorganic matter, advantageously Si₃N₄ or SiO₂.

6. The method of forming an organized network of ZnO nanorods of claim 1, wherein the openings are formed by electron beam lithography.

7. The method of forming an organized network of ZnO nanorods of claim 1 wherein the epitaxial growth of the nanorods is carried out in the absence of catalyst.

8. The method of forming an organized network of ZnO nanorods of claim 1, wherein the epitaxial growth of the nanorods is carried out by means of the MOCVD technique.

9. The method of forming an organized network of ZnO nanorods of claim 1, wherein the epitaxial growth of the nanorods is carried out at high temperature, advantageously in the range from 700° C. to 1,000° C.

10. The method of forming an organized network of ZnO nanorods of claim 1, wherein for the epitaxial growth of the nanowires, the molar ratio of the oxygen precursor, for example, N₂O, to the zinc precursor, for example, DEZn, is in the range from 100 to 1,000, advantageously equal to 600.
